(19) United States
(12) Patent Application Publication
(10) Pub. No.: US 2010/0163982 A1
(43) Pub. Date: Jul. 1, 2010

(54) SEMICONDUCTOR DEVICE FOR HIGH VOLTAGE AND METHOD FOR MANUFACTURING THE SAME

(76) Inventor: Duck-Ki Jang, Songpa-gu (KR)

Correspondence Address: SHERR & VAUGHN, PLLC, 620 HERNDON PARKWAY, SUITE 320, HERNDON, VA, 20170, US

(21) Appl. No.: 12/649,177

(22) Filed: Dec. 29, 2009

(30) Foreign Application Priority Data
Dec. 30, 2008 (KR) 10-2008-0137537

(51) Int. Cl. H01L 29/78; H01L 21/336

(52) U.S. Cl. 257/335; 438/296; 257/E29.256; 257/E21.417

(57) ABSTRACT

A semiconductor device which may be for a high voltage and a method of manufacturing the same. A semiconductor device may include a first conductivity-type well formed on and/or over a substrate, a second conductivity-type drift region formed on and/or over a first conductivity-type well, an isolation layer formed on and/or over a first conductivity-type well, an isolation layer defining an isolation region and/or an active region, a gate pattern formed on and/or over a predetermined upper surface of a second conductivity-type drift region and/or a first conductivity-type well at an active region of a substrate, and/or second conductivity-type source and/or drain regions formed on and/or over second conductivity-type drift regions at two sides of a gate pattern. A gate pattern and/or a drift region of a semiconductor device may be formed substantially without gaps.

The present application claims priority under 35 U.S.C. 119 to Korean Patent Application No. 10-2008-0137537 (filed on Dec. 30, 2008) which is hereby incorporated by reference in its entirety.

### BACKGROUND

Embodiments relate to a semiconductor device and a method of manufacturing a semiconductor device. Some embodiments relate to a semiconductor device for relatively high voltage and a method of manufacturing the same.

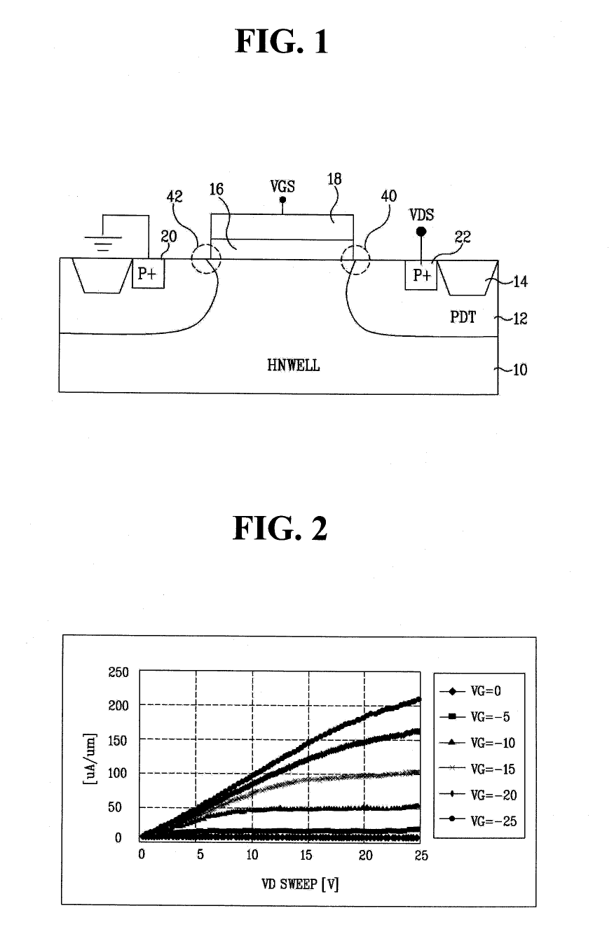

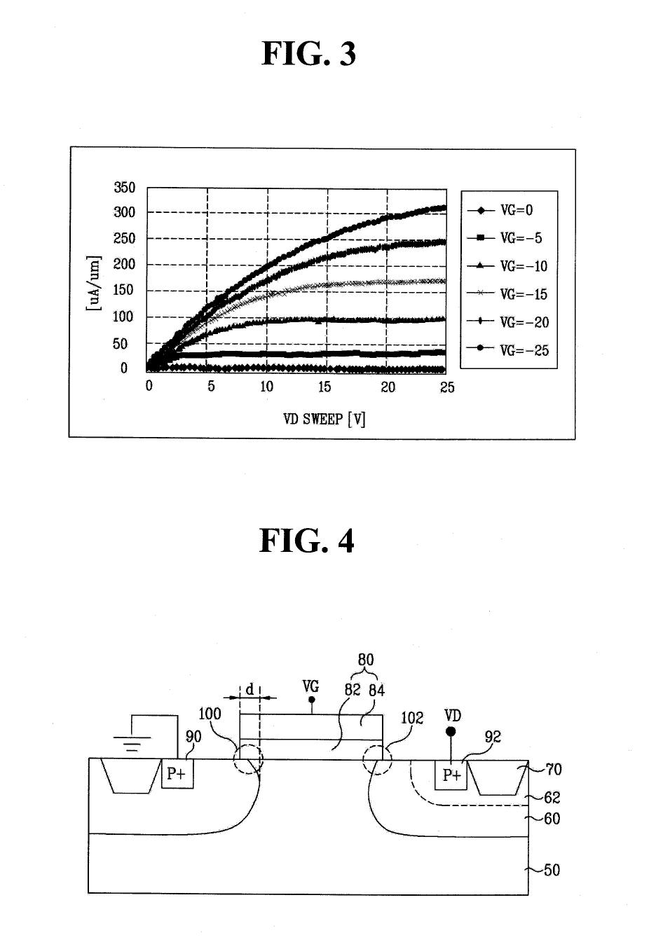

Referring to example FIG. 1, a sectional view illustrates a high voltage transistor. A high voltage transistor may include high voltage N-type well (HNWELL) 10, P-type drift region (PDT) 12, isolation layer 14, a gate pattern including gate insulation layer 16 and/or gate electrode 18, high density P-type source region and/or p-type drain region 22. Referring to example FIG. 2, a graph illustrates relatively abnormal current/voltage characteristics of a high voltage PMOS transistor illustrated in FIG. 1. Referring to example FIG. 3, a graph illustrates relatively normal characteristics of a high voltage PMOS transistor.

A horizontal axis may relate to SWEEP of drain voltage (VD) and/or a vertical axis may relate to drain current (I) based on changes of gate voltage (VG). A relatively normal current/voltage characteristic of a high PMOS transistor may draw a rounded curvature illustrated in FIG. 3. However, in a high voltage PMOS transistor illustrated in FIG. 1, a channel may be cut by gaps 40 and/or 42 between gate pattern 16 and/or 18 and P-type drift region 12. A value of on-resistance (Ron) may be maximized. As on-resistance (Ron) relatively increases, a current-voltage characteristic may be relatively abnormally linear, which may relate to an incurve, as illustrated in FIG. 2.

On-resistance may be configured of source resistance (Rs), drain resistance (Rd) and/or channel resistance (Rch). A transistor having a relatively abnormal incurve may not be used as a high voltage transistor. Drain saturated current (Idsat) of a high voltage transistor having an abnormal incurve characteristic may be approximately 160 mA/μm, in comparison to approximately 250 mA/μm of a relatively normal drain saturated current.

Accordingly, there is a need of a semiconductor device for relatively high voltage and a method of manufacturing the same.

### SUMMARY

Embodiments relate to a semiconductor device and a method of manufacturing a semiconductor device. Some embodiments relate to a semiconductor device for a relatively high voltage and a method of manufacturing the same. According to embodiments, a semiconductor device may be for a high voltage. In embodiments, a semiconductor device and a method of manufacturing the same may be able to relatively improve on-resistance, which may cause a relatively abnormal incurve characteristic to be a normal current/voltage characteristic.

According to embodiments, a semiconductor device may include a first conductivity-type well formed on and/or over a substrate. In embodiments, a semiconductor device may include a second conductivity-type drift region formed on and/or over a first conductivity-type well. In embodiments, a semiconductor device may include an isolation layer formed on and/or over a first conductivity-type well, which may define an isolation region and/or an active region. In embodiments, a semiconductor device may include a gate pattern formed on and/or over predetermined upper surfaces of a second conductivity-type drift region and/or first conductivity-type well at an active region of a substrate. In embodiments, a semiconductor device may include second conductivity-type source and/or drain regions formed on and/or over second conductivity-type drift regions at two sides of a gate pattern.

According to embodiments, a method of manufacturing a semiconductor device may include forming a first conductivity-type well on and/or over a substrate. In embodiments, a method of manufacturing a semiconductor device may include forming a second conductivity-type drift region on and/or over a first conductivity-type well. In embodiments, a method of manufacturing a semiconductor device may include forming an isolation layer on and/or over a first conductivity-type well, which may define an isolation region and/or an active region. In embodiments, a method of manufacturing a semiconductor device may include forming a gate pattern on and/or over predetermined upper surfaces of a second conductivity-type drift region and/or a first conductivity-type well at an active region formed on and/or over a substrate. In embodiments, a method of manufacturing a semiconductor device may include forming second conductivity-type source and/or drain regions formed on and/or over second conductivity-type drift regions at two sides of a gate pattern

According to embodiments, a gate pattern and/or a drift region of a semiconductor device for a relatively high voltage may be formed substantially without gaps, which may prevent a channel from being cut. In embodiments, a value of on-resistance may be relatively increased and/or a relatively abnormal incurve characteristic of a transistor may be relatively improved.

### DRAWINGS

Example FIG. 1 is a sectional view illustrating a high voltage transistor;

Example FIG. 2 is a graph illustrating relatively abnormal current/voltage characteristics of a high voltage PMOS transistor.

Example FIG. 3 is a graph illustrating relatively normal current/voltage characteristics of a high voltage PMOS transistor.

Example FIG. 4 is a sectional view illustrating a semiconductor device in accordance with embodiments.

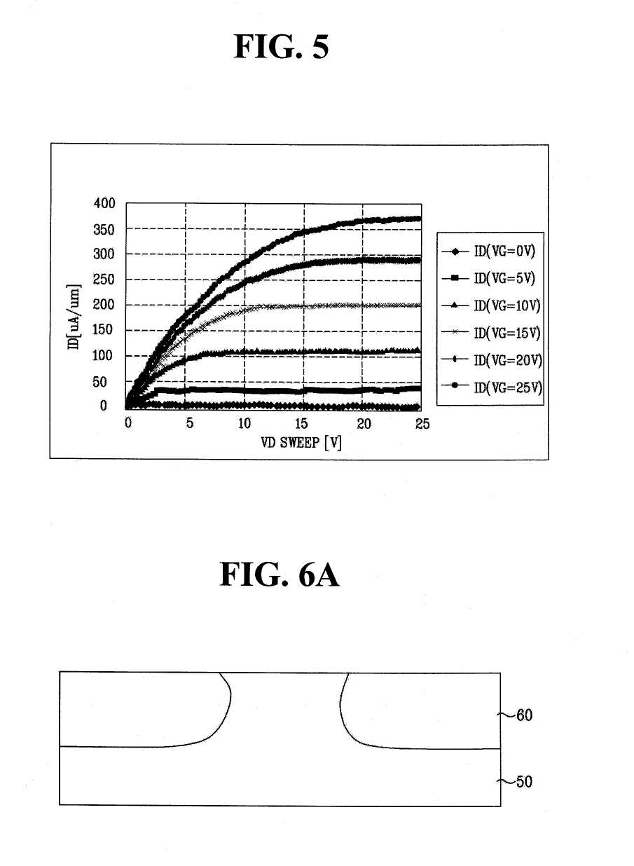

Example FIG. 5 is a graph illustrating current/voltage characteristics of a high PMOS transistor in accordance with embodiments.

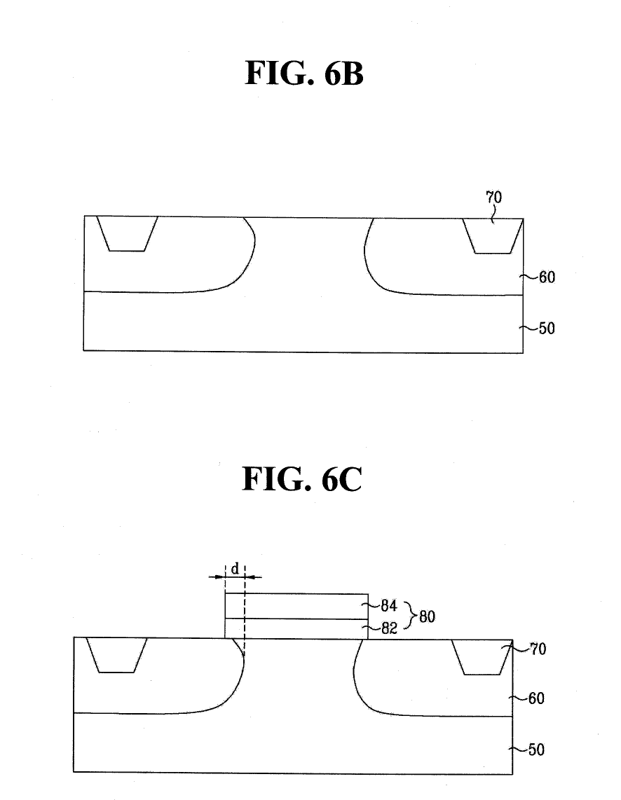

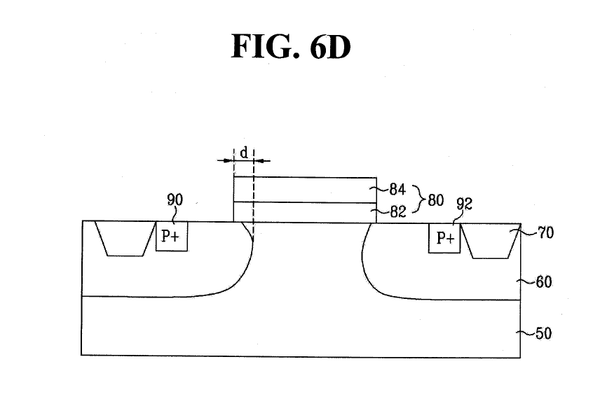

Example FIG. 6A to FIG. 6D are sectional views illustrating a method of manufacturing a semiconductor device in accordance with embodiments.

### DESCRIPTION

Embodiments relate to a semiconductor device and a method of manufacturing a semiconductor device. Some embodiments relate to a semiconductor device for relatively high voltage and a method of manufacturing the same. According to embodiments, a first conductivity-type may include an N-type and/or a second conductivity-type may include a P-type high voltage PMOS transistor. Embodiments may be applicable if a first conductivity-type includes a P-type and/or a second conductivity-type includes an N-type NMOS transistor.

Referring to example FIG. 4, a sectional view illustrates a semiconductor device for a relatively high voltage in accordance with embodiments. According to embodiments, a semiconductor device for a high voltage may be a high voltage PMOS transistor used, for example, to display. In embodiments, a high voltage PMOS transistor illustrated in FIG. 4 may be applicable to approximately 0.13 μm Active Matrix OLED (AMOLED). In embodiments, a first conductivity-type, for example, high voltage N-type well 50 may be formed on and/or over a substrate. In embodiments, second conductivity-type, for example, P-type drift region (PDT) 60 may be formed on and/or over N-type well 50. In embodiments, reference numeral 62 may relate to a depletion layer.

According to embodiments, isolation layer 70 may define an isolation region and/or an active region, which may be formed on and/or over a P-type drift region of N-type well 50. In embodiments, gate pattern 80 may be formed on and/or over an active region on and/or over a substrate, which may be over a predetermined upper surface region of P-type drift region 60 and/or a predetermined upper surface region of N-type well 50. In embodiments, gate pattern 80 may include gate insulation layer 82 and/or gate electrode 84.

According to embodiments, gate insulation layer 82 may be formed on and/or over a predetermined upper surface area of P-type drift region 60 and/or N-type well 50. In embodiments, a gate electrode may be formed on and/or over gate insulation layer 82. In embodiments, width (d) of an overlapped area between P-type drift region 60 and gate pattern 80 may be formed, which may be between approximately 0.1 μm and 0.3 μm. In embodiments, high density P-type (P+) source region 90 and/or high density P-type (P+) drain region 92 may be formed at two side areas of a P-type drift region next to gate pattern 80.

According to embodiments, an interlayer insulation layer may be formed on and/or over a front surface of a substrate which may cover gate pattern 80. In embodiments, first and/or second contact plugs may pass through an interlayer insulation layer to be respectively electrically connected to source region 90 and/or drain region 92. According to embodiments, a semiconductor device for a relatively high voltage as illustrated in FIG. 4 may include a high voltage transistor, such that voltage (VG) applied to gate electrode 84 and/or a voltage applied to drain region 92 may be substantially the same. In embodiments, a voltage applied to gate electrode 84 may be approximately 1.5V, 5.5V and/or 20V. In embodiments, source region 90 may be grounded.

Referring to example FIG. 5, a graph illustrates current/voltage characteristics of a high voltage PMOS transistor illustrated in FIG. 4. According to embodiments, a horizontal axis may relate to SWEEP of drain voltage (VD) and/or a vertical axis may relate to drain current (ID). In embodiments, characteristics of drain current (ID) may change based on changes of gate voltage (VG). In embodiments, gate pattern 80 and/or P-type drift region 60 may be formed substantially without gaps, for example 40, 42 as illustrated in FIG. 1, such that a channel may not be cut by a gap. In embodiments, a value of on-resistance may relatively increase and/or relatively abnormal incurve characteristic of a transistor as illustrated in FIG. 2 may be relatively improved.

According to embodiments, a method of manufacturing a semiconductor device for a high voltage in accordance with embodiments is illustrated. Referring to example FIG. 6A to FIG. 6D, sectional views illustrate a method manufacturing a semiconductor device in accordance with embodiments. Referring to FIG. 6A, a high voltage first conductivity-type, for example, N-type well 50 may be formed on and/or over a substrate. In embodiments, a second conductivity-type, for example, P-type drift region 60 may be formed on and/or over N-type well 50. In embodiments, a semiconductor may be formed substantially without gaps, for example 40, 42 illustrated in FIG. 1. In embodiments, a dose amount of impurity injected to form P-type drift region 60 may be relatively increased and/or energy of impurity ion injection may be relatively decreased. As illustrated in FIG. 4, gaps 100 and/or 102 formed between gate pattern 80 and P-type drift region 60 may be substantially prevented.

Referring to FIG. 6B, isolation layer 70 may define an isolation region and/or an active region which may be formed on and/or over N-type well 60. According to embodiments, isolation layer 70 may be formed on and/or over P-type drift region 60 of N-type well 50. In embodiments, isolation layer 70 illustrated in FIG. 6B may form a trench on and/or over a substrate by a shallow trench isolation (STI) process, and/or a chemical mechanical polishing (CMP) process may be performed to complete formation of isolation layer 70 after an insulating material may gap-fill a trench. In embodiments, isolation layer 70 may be formed by a local oxidation of silicon (LOCOS) process. In embodiments, a semiconductor device may not be substantially influenced by a formation order of isolation layer 70 and P-type drift region 60. In embodiments, P-type drift region 60 may be formed after isolation layer 70 may be formed.

Referring to FIG. 6C, gate pattern 80 may be formed at two side of a predetermined upper surface of P-type drift region and/or a predetermined upper surface of N-type well 50, which may be on and/or over an active region of a substrate. In embodiments, a gate insulating material and/or a polysilicon layer may be multilayered sequentially on and/or over a front surface of a substrate illustrated in FIG. 6B. In embodiments, a photoresist pattern may be formed on and/or over polysilicon be a photolithography process. In embodiments, an etching process may be performed using a photoresist as mask, and/or gate pattern 80 may be formed as illustrated in FIG. 6C. In embodiments, gate pattern 80 may be overlapped with an upper surface of P-type drift region 60 to width (d) between approximately 0.1 μm and 0.3 μm, for example approximately 0.2 μm. In embodiments, a width of gate pattern 80 may be relatively larger than a width of gate pattern 16 and/or 18 illustrated in FIG. 1.

Referring to FIG. 6D, high density P-type source region 90 and/or high density P-type drain region 92 may be formed on and/or over P-type drift regions 60 at two sides of gate pattern 80. According to embodiments, for example after source region 90 and/or drain region 92 may be formed, an interlayer insulation layer may be formed on and/or over a front surface of a substrate which may cover gate pattern 80. In embodiments, first and/or second contact holes may be formed through an interlayer insulation layer to expose source region 90 and/or drain region 92. In embodiments, first and/or second contact plugs may be formed on and/or over first and/or second contact holes, respectively. According to embodiments, a semiconductor device for a relatively high voltage in accordance with embodiments may have superior effects in comparison to a PMOS transistor having a P-type as a first conductivity-type and/or a N-type as a second conductivity-type, for example it may have an N-type as a first conductivity-type and/or a P-type as a second conductivity-type.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a first conductivity-type well over a substrate;
a second conductivity-type drift region over said first conductivity-type well;
an isolation layer over said first conductivity-type well defining an isolation region and an active region;
a gate pattern over a predetermined upper surface of said second conductivity-type drift region and said first conductivity-type well at said active region of said substrate; and
second conductivity-type source and drain regions over said second conductivity-type drift regions at two sides of said gate pattern.

2. The apparatus of claim 1, wherein said first conductivity-type comprises an N-type and said second conductivity-type comprises a P-type.

3. The apparatus of claim 1, wherein a width of an overlapped region between said second conductivity-type drift region and said gate pattern over said second conductivity-type drift region is between approximately 0.1 μm and 0.3 μm.

4. The apparatus of claim 1, comprising:
an interlayer insulation layer over a front surface of the substrate which substantially covers said gate pattern; and
first and second contact plugs electrically connected to said source and drain regions over said interlayer insulation layer.

5. The apparatus of claim 1, comprising a semiconductor device including a high voltage transistor.

6. The apparatus of claim 1, wherein said apparatus is configured to be used to display.

7. The apparatus of claim 1, wherein a voltage applied to a gate electrode is substantially the same as a voltage applied to said drain region.

8. The apparatus of claim 7, wherein gaps are substantially prevented from being formed between said gate pattern and said second conductivity-type drift region.

9. The apparatus of claim 1, wherein a trench over said isolation layer is gap-filled by an insulating layer.

10. The apparatus of claim 9, wherein the trench is formed by a shallow trench isolation process and a chemical mechanical polishing process is performed to complete formation of isolation layer.

11. A method comprising:
forming a first conductivity-type well over a substrate;
forming a second conductivity-type drift region over said first conductivity-type well;
forming an isolation layer over said first conductivity-type well defining an isolation region and an active region;
forming a gate pattern over a predetermined upper surface of said second conductivity-type drift region and said first conductivity-type well at said active region of said substrate; and
forming second conductivity-type source and drain regions over said second conductivity-type drift regions at two sides of said gate pattern.

12. The method of claim 11, wherein said first conductivity-type comprises an N-type and said second conductivity-type comprises a P-type.

13. The method of claim 11, wherein a width of an overlapped region between said second conductivity-type drift region and said gate pattern over said second conductivity-type drift region is between approximately 0.1 μm and 0.3 μm.

14. The method of claim 11, comprising:
forming an interlayer insulation layer over a front surface of the substrate which substantially covers said gate pattern;
forming first and second contact holes over said interlayer insulation layer to expose said source region and said drain regions; and
forming first and second contact plugs electrically connected to said source and drain regions over said respective first and second holes.

15. The method of claim 11, comprising a semiconductor device including a high voltage transistor.

16. The method of claim 11, wherein said apparatus is configured to be used to display.

17. The method of claim 11, wherein a voltage applied to a gate electrode is substantially the same as a voltage applied to said drain region.

18. The method of claim 17, wherein gaps are substantially prevented from being formed between said gate pattern and said second conductivity-type drift region.

19. The method of claim 11, wherein a trench over said isolation layer is gap-filled by an insulating layer.

20. The method of claim 19, wherein the trench is formed by a shallow trench isolation process and a chemical mechanical polishing process is performed to complete formation of isolation layer.
